(19) United States
(12) Patent Application Publication
(10) Pub. No.: US 2007/0085161 A1
(43) Pub. Date: Apr. 19, 2007

(54) Integrated semiconductor temperature detection apparatus and method

(76) Inventors: Richard S. Bickham, Cary, IL (US); Dale R. Anderson, Colleyville, TX (US)

Correspondence Address: MOTOROLA, INC., 1303 EAST ALGONQUIN ROAD, IL01/3RD, SCHAUMBURG, IL, 60196, US

(21) Appl. No.: 11/252,086

(22) Filed: Oct. 17, 2005

(51) Int. Cl. H01L 29/00

(52) U.S. Cl. 257/499

(57) ABSTRACT

An integrated semiconductor apparatus (300)(such as, but not limited to, a radio frequency power device) is comprised of a plurality of active device cells (302, 303), a plurality of temperature detectors (304, 305), and a controller (308). The active device cells are preferably each comprised of a plurality of active devices having a common signal input and a common signal output. The temperature detectors are preferably configured and arranged such that each of the temperature detectors detects a temperature indicator (such as infrared radiation) as corresponds to at least one of the active device cells but not, at least in substantial measure, other of the active device cells. The controller preferably operably couples to these temperature detectors and receives their detected output and generates control signals that operate on the inputs to the active device cells in a manner that changes the relative active device cell temperatures.

### TECHNICAL FIELD

This invention relates generally to integrated semiconductor apparatuses and more particularly to temperature compensated performance.

### BACKGROUND

Radio frequency power transistors and integrated circuits are known in the art and typically comprise a large number of separate cells. These cells usually operate in parallel with one another. Ideally such devices will distribute an incoming radio frequency signal to all cells as comprise the transistor/circuit such that each cell receives an input signal having an identical amplitude and phase. Similarly, and again ideally, these devices should transform the impedance presented to the transistor/circuit output in a manner that loads each cell with an impedance of equal magnitude and phase. In such a case all of the cells can be expected to exhibit the same gain, efficiency, output power, and dissipation presuming, of course, that all cells are operating at a same temperature.

Unfortunately, electrical imbalances can and do occur. For example, mutual coupling between on-chip metallization patterns will contribute to electrical imbalance. Mutual coupling between individual cell wirebonds, too, can similarly result in electrical imbalance. Furthermore, these problems typically become more pronounced as the frequency of the input signal increases. Other problems are also known. For example, on-chip cell proximity will often lead to a thermally unbalanced condition. This can occur, for example, when cells near the center of the transistor/integrated circuit operate at higher temperatures than cells at the edges of the device.

Additionally, an on-chip thermally balanced condition (wherein each active device cell is operating at substantially the same nominal temperature) does not necessarily coincide with an electrically balanced condition overall. This, in turn, may result in sub-optimum performance even in a thermally balanced state, with performance being any of (or a combination of) several performance parameters typical of radio frequency power amplifiers including (but not limited to) gain, efficiency, output power, and linearity.

In the past, efforts to improve thermal balance often occur at the expense of electrical balance. For example, non-uniform cell feed metallization patterns and non-uniform wirebond configurations, resistive ballasting of individual cells, compromised chip layout, and other design factors have been considered to attempt to improve thermal balance notwithstanding that such design considerations generally tend to diminish electrical balance with respect to the resultant apparatus. This is particularly true for higher frequency applications where simulation tools and models often lack sufficient accuracy to permit the reliable design of an apparatus that exhibits both sufficient electrical balance and thermal balance. These efforts are typically fixed for a given device design and are subject to performance variations owing to manufacturing variations, frequency of operation, and so forth.

Unfortunately, these difficulties in turn can lead to less than optimum devices. Any imbalance with respect to the radio frequency input drive, load impedance, or temperature will typically result in cells that operate at different gains, efficiency, and/or saturated output power levels. These, in turn, can negatively impact critical overall device performance including overall gain, efficiency, and/or linearity.

### BRIEF DESCRIPTION OF THE DRAWINGS

The above needs are at least partially met through provision of the integrated semiconductor temperature detection apparatus and method described in the following detailed description, particularly when studied in conjunction with the drawings, wherein:

FIG. 1 comprises a flow diagram as configured in accordance with various embodiments of the invention;

FIG. 2 comprises a flow diagram as configured in accordance with various embodiments of the invention;

FIG. 3 comprises a block diagram as configured in accordance with various embodiments of the invention;

FIG. 4 comprises a top plan detail view of a typical high power radio frequency bipolar junction transistor as configured in accordance with various embodiments of the invention; and

FIG. 5 comprises a top plan detail view of a typical high power Laterally Diffused Metal Oxide Silicon (LDMOS) field effect transistor as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Generally speaking, pursuant to these various embodiments, an integrated semiconductor apparatus (such as, but not limited to, a radio frequency power device) is comprised of a plurality of active device cells, a plurality of temperature detectors, and a controller. The active device cells are preferably each comprised of a plurality of active devices having a common signal input and a common signal output. The temperature detectors are preferably configured and arranged such that each of the temperature detectors detects a temperature indicator as corresponds to at least one of the active device cells but not, at least in substantial measure, others of the active device cells. The controller preferably operably couples to these temperature detectors and receives their detected output. Optionally, the controller may also be selectively coupled to an external signal input that can be used in lieu of (and directed, for example, by the state of an external mode select input signal) the outputs from the plurality of temperature detectors.

In a preferred though optional approach, the integrated semiconductor apparatus further comprises a plurality of signal conditioning units that each couple between the common signal input of a corresponding one of the active device cells and a shared signal input. These signal conditioning units are preferably responsive to and are at least partially controlled by the controller. This, in turn, permits the signal conditioning units to control the magnitude and/or the phase of the signal being provided to each of the active device cells.

So configured, the controller can control the temperature performance of at least some of the active device cells (for example, by at least attempting to equalize the temperature indicators as are yielded by each of the active device cells and sensed by a corresponding temperature detector, or by minimizing or maximizing the external signal input to the controller in order to optimize an operational performance parameter proportional to the external signal input of the radio frequency power device). This, in turn, permits the device designer greater latitude and design freedom with respect to such a device. In particular, the device can often be operated with apparent thermal balance notwithstanding a lack of such balance when operating the device sans temperature compensation as taught herein. Those skilled in the art will appreciate that these teachings are readily employed within the framework of a given integrated circuit and do not require outboard detection and/or off-chip signal monitoring or control.

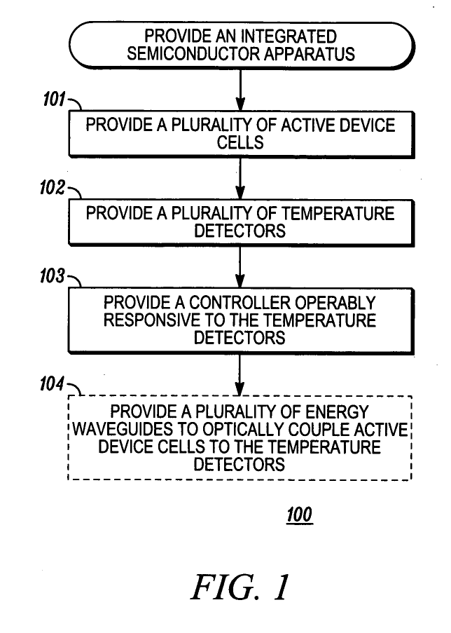

These and other benefits may become clearer upon making a thorough review and study of the following detailed description. Referring now to the drawings, and in particular to FIG. 1, these teachings set forth a process 100 that is useful with respect to providing an integrated semiconductor apparatus. A first step 101 provides for a plurality of active device cells. In a preferred embodiment the active device cells are each comprised of a plurality of active devices having a common signal input and a common signal output. Such configurations and their manner of construction are well known in the art and require no further description here.

A second step 102 then provides for a plurality of temperature detectors. These temperature detectors are preferably positioned to each be responsive to the temperature from at least some of the active device cells but not, at least in substantial measure, temperature from at least some others of the active device cells. In a preferred configuration, each such temperature detector is essentially only responsive to a temperature as corresponds to a single given one of the active device cells and not influenced to any great degree by any other active device cells (including, preferably, other active device cells as may be adjacent to the active device cell to which the temperature detector does respond).

Various temperature detectors are known in the art. While these teachings are likely applicable to use of many or all such temperature detectors as are presently known or as are hereafter developed, pursuant to a preferred approach these temperature detectors comprise infrared energy detectors. Such infrared energy detectors are known in the art.

A next step 103 of this process 100 provides a controller that is operably responsive to the plurality of temperature detectors. This controller will preferably comprise an active device cell input controller (and more particularly a signal magnitude controller and/or a signal phase controller) as will be described in more detail below. So configured, the controller will be able to influence and/or control the signals as are fed to each of the active device cells as a function, at least in part, of temperature differentials as may exist therebetween.

As noted, in a preferred approach, the temperature detectors comprise infrared energy detectors. In many cases it may be possible to place these temperature detectors relatively close to the active device cells that they are to monitor, but in most cases these temperature detectors will more likely be located at least somewhat remotely from the active device cells (albeit still within a commonly shared integrated semiconductor platform). To facilitate these temperature detectors being able to detect the temperatures of the active device cells, this process 100 may also provide for the optional step 104 of providing a plurality of energy waveguides to optically couple at least some of the active device cells to corresponding ones of the plurality of temperature detectors.

Active device cells and temperature detectors as described above are readily formed using standard silicon-based semiconductor fabrication techniques. Energy waveguides may be fabricated within that same context using, for example, gallium arsenide fabrication (or other so-called III-V materials-based fabrication) techniques. Various teachings are available in the art which describe combined silicon bipolar/metal oxide semiconductor elements and gallium arsenide elements in a common integrated semiconductor platform. Therefore, for the sake of brevity and the preservation of narrative focus, additional details regarding the use of such known techniques will not be provided here.

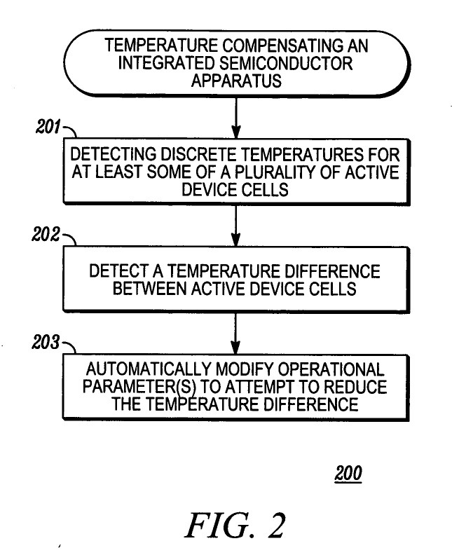

As already noted, an integrated semiconductor apparatus formed in conformance with the above teachings will support the control of signals as are input to such active device cells as a function, at least in part, of monitored temperatures for those active device cells. Referring now to FIG. 2, a corresponding illustrative process 200 will be presented.

Pursuant to this process for temperature compensating an integrated semiconductor apparatus, a first step 201 provides for detecting, for at least some of a plurality of active device cells as comprise that integrated semiconductor apparatus, and wherein each of the active device cells comprises a plurality of active devices having a common signal input and a common signal output, a temperature for at least some of the active device cells but not, at least in substantial measure, temperature influences from at least some others of the active device cells. This process 200 then provides the step 202 of detecting a temperature difference as between at least two of the active device cells. For example, this step 202 encompasses detecting when one of the active device cells becomes hotter than other of the active device cells. In an optional but preferred approach, this step 202 comprises detecting such a temperature difference by detecting infrared energy values for at least some, and preferably all, of the active device cells.

Pursuant to a next step 203, this process 200 then automatically modifies at least one operational parameter to attempt to reduce the temperature difference in response to detecting such a temperature difference. More particularly, and pursuant to a preferred approach, this can comprise automatically modifying a signal as is input to the common signal input of one or more of the active device cells. This modification can comprise, for example, modifying the magnitude of a given input signal (by increasing or decreasing the amplitude of the input signal) and/or by modifying the phase of that input signal. So configured, for example, this mechanism can be employed to attempt to, for example, reduce the magnitude of the signal as is applied to a given one of the active device cells in order to reduce the temperature as corresponds to that active device cell.

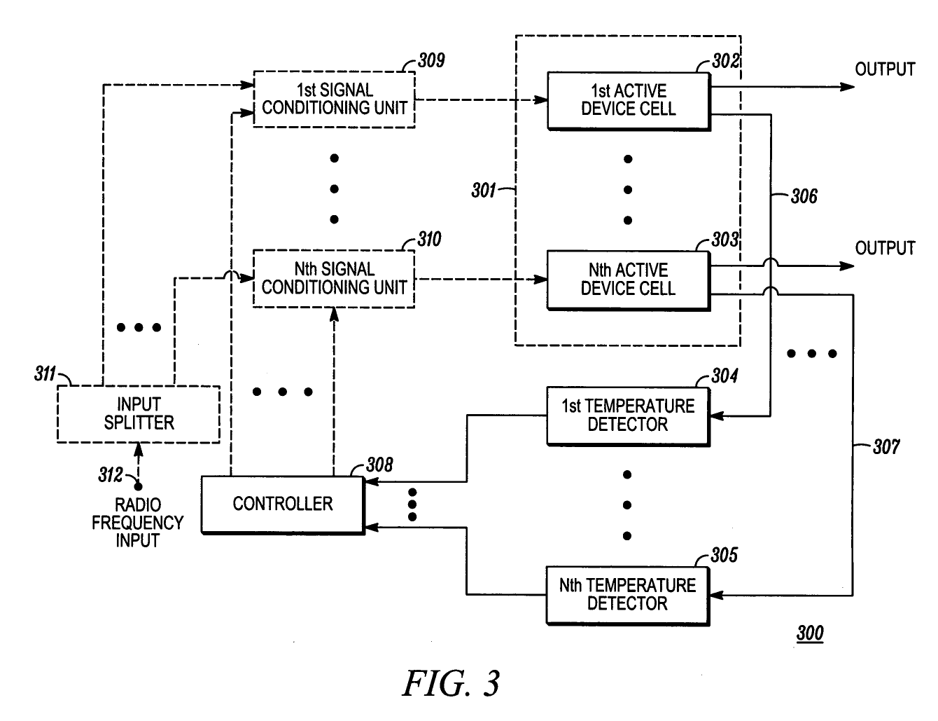

Those skilled in the art will appreciate that the above-described processes are readily enabled using any of a wide variety of available and/or readily configured platforms. Referring now to FIG. 3, an illustrative approach to such a platform will be provided. For the purposes of illustration, the depicted integrated semiconductor apparatus 300 comprises a radio frequency power device.

This integrated semiconductor apparatus 300 comprises, in part, a first portion 301 that features a plurality of active device cells (represented here by a first active device cell 302 through an Nth active device cell 303 where “N” comprises an integer greater than “1”). This first portion 301 serves as an amplifier and is intended to amply an incoming radio frequency signal. In this embodiment, it is presumed that each of the active device cells is comprised of a corresponding plurality of transistors. Such an architectural approach is well understood in the art.

As per the teachings set forth above, this integrated semiconductor apparatus 300 further comprises a plurality of temperature detectors (represented here by a first temperature detector 304 through an Nth temperature detector 305). These temperature detectors preferably comprise infrared energy detectors and are configured and arranged such that a first temperature detector 304 as corresponds to at least a first one of the active device cells (such as, in this embodiment, the first active device cell 302) will detect a corresponding temperature indicator as corresponds to that active device cell but not, at least in substantial measure, a temperature indicator as corresponds to a second one of the active device cells (such as, in this embodiment, the Nth active device cell 303). In this embodiment, where the temperature detectors comprise infrared energy detectors, the temperature indicator will preferably comprise infrared energy as is radiated by each of the active device cells during their operation.

To facilitate this detection, and pursuant to a preferred approach, the integrated semiconductor apparatus 300 further comprises a plurality of energy waveguides 306 and 307. In a preferred approach a first energy waveguide 306 optically couples the first active device cell 302 to the first temperature detector 304, and so forth. So configured, those skilled in the art will recognize and appreciate that each temperature detector is able to detect and respond to the temperature as substantially corresponds to only a given one of the active device cells in substantial isolation from the heat contribution of others of the active device cells.

This, in turn, permits a controller 308 as operably couples to the temperature detectors to receive useful information regarding the essentially isolated temperature performance of each of the active device cells. The controller 308 can comprise any desired platform as will perform these relatively straight forward actions. For example, the comparison of the incoming temperature information can be realized using differential amplifier arrays or the like. As another example, partially or wholly programmable signal processing circuitry operating with appropriate algorithmic control can be employed if desired.

So configured, via soft or hard programming, the controller 308 is able to control the temperature performance of at least some of the plurality of active device cells by, for example, at least attempting to equalize the temperature indicators as are provided for each of the active device cells as described above.

To facilitate such control, and pursuant to an optional but preferred approach, the integrated semiconductor apparatus 300 further comprises a plurality of signal conditioning units (represented here by a first signal conditioning unit 309 through an Nth signal conditioning unit 310). These signal conditioning units each receive a radio frequency signal as is provided by an input splitter 311 (which in turn receives an original radio frequency signal from a radio frequency input 312 of choice). In a preferred approach each signal conditioning unit has its output coupled to the common signal input of a corresponding one of the active device cells. For example, as illustrated, the first signal conditioning unit 309 has an output that couples to the common signal input of the first active device cell 302.

These signal conditioning units preferably comprise signal magnitude controllers and/or signal phase shifters and have control inputs that are operably coupled to corresponding control outputs of the above-described controller 308. So configured, it may be seen that the controller 308 is readily able to control the magnitude and/or phase of the radio frequency signal as is discretely fed to each of the active device cells. This control is then readily leveraged by the controller 308 as necessary to at least attempt to equalize the temperature performance of each of the active device cells.

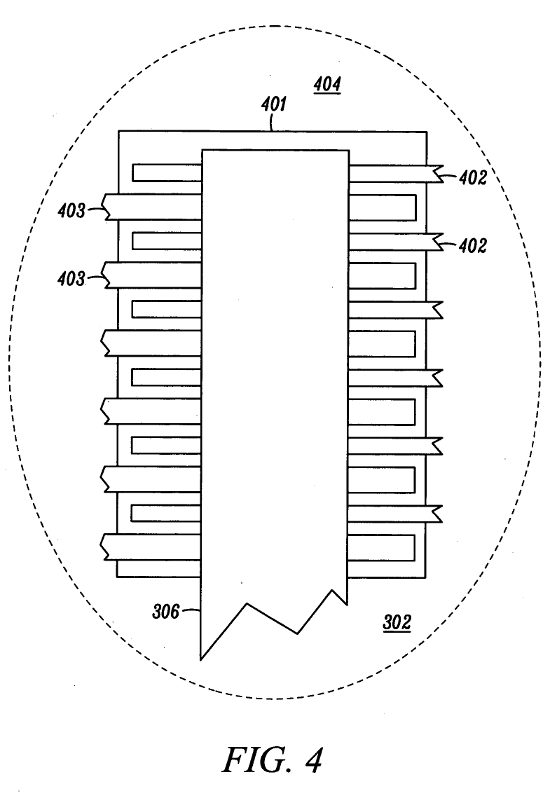

As described above, these teachings may be employed within the context of a self-contained integrated structure such as an integrated semiconductor apparatus. To aid in illustrating this point, and referring now to FIG. 4, the first active device cell 302 referred to above may comprise a silicon base diffusion 401 as diffused into at least a part of a silicon collector region 404 and having a plurality of base contact metallization fingers 402 connected to base diffusions 401, and emitter contact metallization fingers 403 connected to a plurality of emitter diffusions into base diffusion 401 formed thereon in accordance with well-understood bipolar junction transistor prior art technique.

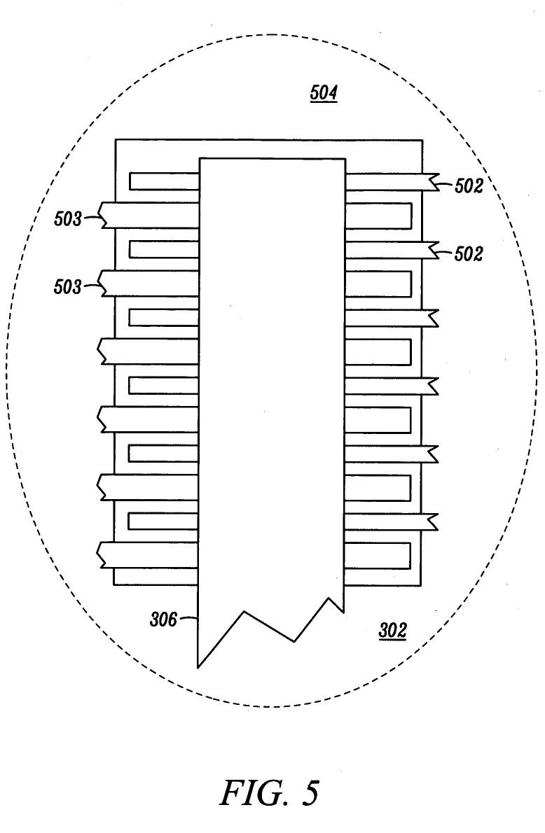

Alternatively, and referring now to FIG. 5, the first active device cell 302 referred to above may comprise a plurality of silicon gate regions formed within at least a part of a silicon source region 504 and having a plurality of gate contact metallization fingers 502 connected to said gate regions, and drain contact metallization fingers 503 connected to a plurality of drain diffusions into source region 504 formed thereon in accordance with well-understood Laterally Diffused Metal Oxide Silicon (LDMOS) transistor prior art technique.

In either case, an energy waveguide 306 is then formed, for example, of an optical dielectric material that will carry the infrared energy of interest to the temperature detector (not shown). In a preferred approach this energy waveguide 306 overlies at least a part of the emitter (or drain) regions, a base (or gate regions), and collector (or source regions) that comprise the active device cell.

So configured, infrared energy (which will typically be proportional to cell temperature) couples from each cell into a corresponding optical dielectric waveguide and propagates therethrough to a corresponding detector circuit that also optically couples thereto to receive the propagating infrared content. As such cells are typically significantly hotter during use than other parts of such an integrated semiconductor apparatus, it may be desirable to route the waveguides over cooler parts of the chip such that the source infrared signal within the waveguide will be largely unaffected by any infrared noise (that is, infrared energy that couples into the waveguide from substantially cooler parts of the chip over which the optical dielectric waveguide is routed) during its transit.

Those skilled in the art will recognize and appreciate the considerable differences between these teachings and prior practice. In the past, thermal balance of cells as are used in a radio frequency power device has been largely achieved via the design of the cell layout, on-chip metallization patterns, resistor ballasting profiles, and wirebonding physical profiles. Though sometimes effective, these approaches are essentially fixed for a given device design. These approaches also vary with respect to successful implementation as a function of such things as manufacturing variations and will also exhibit variable performance effectiveness as the incoming frequency changes. In contrast, the teachings presented herein permit on-chip identification of temperature imbalance between the cells of a radio frequency power device in real time under the actual operating conditions of the radio frequency power device (using, in a preferred embodiment, infrared sensing, routing, and detection).

These teachings are therefore seen to permit on-frequency control and performance optimization of single chip radio frequency power devices within the chip itself and without a need for external radio frequency circuitry. These teachings further permit finer performance tuning as compared to past efforts due, at least in part, to the granularity of adjustment that becomes possible via this control at the individual active device cell level.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept.

We claim:

1. An integrated semiconductor apparatus comprising:
a plurality of active device cells, wherein each of the active device cells comprises a plurality of active devices having a common signal input and a common signal output;
a plurality of temperature detectors configured and arranged such that:
a first temperature detector detects a temperature indicator as corresponds to at least a first one of the active device cells but not, at least in substantial measure, a temperature indicator as corresponds to a second one of the active device cells;
a second temperature detector detects a temperature indicator as corresponds to at least the second one of the active device cells but not, at least in substantial measure, a temperature indicator as corresponds to the first one of the active device cells;
a controller operably coupled to the first and second temperature detector.

2. The integrated semiconductor apparatus of claim 1 wherein the integrated semiconductor apparatus comprises a Radio Frequency power device.

3. The integrated semiconductor apparatus of claim 1 wherein the plurality of active devices comprises a plurality of transistors.

4. The integrated semiconductor apparatus of claim 1 wherein the plurality of temperature detectors comprise a plurality of infrared energy detectors.

5. The integrated semiconductor apparatus of claim 4 further comprising a plurality of energy waveguides, wherein a first energy waveguide optically couples at least a part of the first one of the active device cells to the first temperature detector and a second energy waveguide optically couples at least a part of the second one of the active device cells to the second temperature detector.

6. The integrated semiconductor apparatus of claim 1 further comprising a plurality of signal conditioning units, wherein a first signal conditioning unit is coupled to the common signal input of the first one of the active device cells and a second signal conditioning unit is coupled to the common signal input of the second one of the active device cells.

7. The integrated semiconductor apparatus of claim 6 wherein the controller has a plurality of control outputs, wherein a first control output couples to a control input of the first signal conditioning unit and the second control output couples to a control input of the second signal conditioning unit.

8. The integrated semiconductor apparatus of claim 6 wherein the plurality of signal conditioning units comprise a plurality of at least one of:
signal magnitude controllers;
signal phase shifters.

9. The integrated semiconductor apparatus of claim 1 wherein the controller comprises control means for controlling temperature performance of at least some of the plurality of active device cells.

10. The integrated semiconductor apparatus of claim 9 wherein the control means controls the temperature performance, at least in part, by at least attempting to equalize the temperature indicators for the plurality of active device cells.

11. A method of providing an integrated semiconductor apparatus comprising:
providing a plurality of active device cells, wherein each of the active device cells comprises a plurality of active devices having a common signal input and a common signal output;
providing a plurality of temperature detectors positioned to each be responsive to temperature from at least some of the active device cells but not, at least in substantial measure, temperature from at least some others of the active device cells;
providing a controller that is operably responsive to the plurality of temperature detectors.

12. The method of claim 11 further comprising:
providing a plurality of energy waveguides to optically couple at least some of the active device cells to corresponding ones of the plurality of temperature detectors.

13. The method of claim 11 wherein providing a plurality of temperature detectors comprises providing a plurality of infrared energy detectors.

14. The method of claim 11 wherein the controller comprises at least one active device cell input controller.

15. The method of claim 14 wherein the at least one active device cell input controller comprises at least one of:
a signal magnitude controller;
a signal phase controller.

16. A method of temperature compensating an integrated semiconductor apparatus comprising:
detecting, for at least some of a plurality of active device cells as comprise the integrated semiconductor apparatus, wherein each of the active device cells comprises a plurality of active devices having a common signal input and a common signal output, a temperature for at least some of the active device cells but not, at least in substantial measure, temperature from at least some others of the active device cells;
detecting a temperature difference as between at least two of the active device cells;
in response to detecting a temperature difference, automatically modifying at least one operational parameter to attempt to reduce the temperature difference.

17. The method of claim 16 wherein the temperature is indicated by detecting infrared energy value.

18. The method of claim 16 wherein automatically modifying at least one operational parameter to attempt to reduce temperature differences comprises automatically modifying a signal as is input to the common signal input.
